(19) United States
(12) Patent Application Publication
(10) Pub. No.: US 2011/0128032 A1
(43) Pub. Date: Jun. 2, 2011

(54) WAFER FOR TESTING, TEST SYSTEM, AND SEMICONDUCTOR WAFER

(75) Inventors: Daisuke WATANABE, Saitama (JP); Toshiyuki OKAYASU, Saitama (JP)

(73) Assignee: ADVANTEST CORPORATION, Tokyo (JP)

(21) Appl. No.: 12/954,562

(22) Filed: Nov. 24, 2010

Related U.S. Application Data
(63) Continuation of application No. PCT/JP2008/060174, filed on Jun. 2, 2008.

(51) Int. Cl. G01R 31/26

(52) U.S. Cl. 324/762.01

(57) ABSTRACT

Provided is a test wafer that tests a plurality of semiconductor chips that are formed on a semiconductor wafer and that each include an operation circuit and an internal memory. The test wafer comprises a plurality of test circuits that correspond to the plurality of semiconductor chips, supply the operation circuits of the corresponding semiconductor chips with measurement signals, and measure electrical characteristics of signals output by the operation circuits in response to the measurement signals; and a plurality of write circuits that correspond to the plurality of semiconductor chips and each write, to the internal memory of the corresponding semiconductor chip, data corresponding to a measurement result of the corresponding test circuit.

### BACKGROUND

1. Technical Field

The present invention relates to a test wafer, a test system, and a semiconductor wafer. In particular, the present invention relates to a test wafer and a test system for testing a plurality of semiconductor chips formed on a semiconductor wafer and to a semiconductor wafer on which a plurality of semiconductor chips are formed.

2. Related Art

For testing a device under test, an apparatus is known that tests pass/fail of each of a plurality of semiconductor chips formed on a semiconductor wafer, as shown in, for example, Japanese Patent Application Publication No. 2002-222839. This apparatus can be provided with a probe card that can be electrically connected to the semiconductor chips en bloc.

The probe card is formed using a print substrate or the like. By forming a plurality of probe pins on the print substrate, the probe card can be electrically connected to the semiconductor chips en bloc.

One test for a semiconductor chip involves using BOST circuits. In this case, the BOST circuits can be loaded on the probe card, but when a plurality of semiconductor chips on a semiconductor wafer are tested together, a large number of BOST circuits must be loaded thereon and it becomes difficult to mount the BOST circuits on the print substrate of the probe card.

Another test for a semiconductor chip involves using BIST circuits provided in the semiconductor chip. With this method, however, circuits that are not used for actual operation are formed in the semiconductor chip, and this decreases the area in which actual operation circuits of the semiconductor chip can be formed.

When testing a large number of semiconductor chips on a semiconductor wafer, a large number of fail memories must be provided to store the test results of the semiconductor chips. When a large number of fail memories are provided, the area in which the test circuits can be formed is further decreased.

### SUMMARY

Therefore, it is an object of an aspect of the innovations herein to provide a test wafer, a test system, and a semiconductor wafer, which are capable of overcoming the above drawbacks accompanying the related art. The above and other objects can be achieved by combinations described in the independent claims. The dependent claims define further advantageous and exemplary combinations of the innovations herein. According to a first aspect related to the innovations herein, provided is a test wafer that tests a plurality of semiconductor chips that are formed on a semiconductor wafer and that each include an operation circuit and an internal memory. The test wafer comprises a plurality of test circuits that correspond to the plurality of semiconductor chips, supply the operation circuits of the corresponding semiconductor chips with measurement signals, and measure electrical characteristics of signals output by the operation circuits in response to the measurement signals; and a plurality of write circuits that correspond to the plurality of semiconductor chips and each write, to the internal memory of the corresponding semiconductor chip, data corresponding to a measurement result of the corresponding test circuit.

According to a second aspect related to the innovations herein, provided is a test system that tests a plurality of semiconductor chips that are formed on a semiconductor wafer and that each include an operation circuit and an internal memory. The test system comprises a test wafer that is electrically connected to the semiconductor wafer and a control apparatus that controls the test wafer. The test wafer includes a plurality of test circuits that correspond to the plurality of semiconductor chips, supply the operation circuits of the corresponding semiconductor chips with measurement signals, and measure electrical characteristics of signals output by the operation circuits in response to the measurement signals; and a plurality of write circuits that correspond to the plurality of semiconductor chips and each write, to the internal memory of the corresponding semiconductor chip, data corresponding to a measurement result of the corresponding test circuit.

According to a third aspect related to the innovations herein, provided is a semiconductor wafer on which are formed a plurality of semiconductor chips. Each semiconductor chip includes an internal memory; an external memory access terminal connected to an external circuit; and a switch that controls electrical connection between (i) a data terminal and an address terminal of the internal memory and (ii) the external memory access terminal.

The summary clause does not necessarily describe all necessary features of the embodiments of the present invention. The present invention may also be a sub-combination of the features described above.

### BRIEF DESCRIPTION OF THE DRAWINGS

FIG. 1 shows an overview of a test system 400 for testing a plurality of semiconductor chips 310 formed on a semiconductor wafer 310.

FIG. 2 is an exemplary side view of the test wafer 111.

FIG. 3 shows an exemplary configuration of a circuit block 110.

FIG. 4 is a block diagram showing an exemplary functional configuration of the test circuit unit 118.

FIG. 5 is a block diagram showing exemplary functional configurations of a driver unit 172 and a measuring unit 174.

FIG. 6 is a block diagram showing another functional configuration of a driver unit 172 and a measuring unit 174.

FIG. 7 is a block diagram showing an exemplary functional configuration of a semiconductor chip 310.

FIG. 8 shows another exemplary configuration of the test wafer unit 100.

FIG. 9 shows an exemplary configuration of a circuit block 110 in the test wafer 111.

FIG. 10 shows an exemplary functional configuration of a driver unit 172 and a measuring unit 174.

FIG. 11 shows an exemplary configuration of a circuit block 120.

FIG. 12 shows connections between the test wafer 111, the connection wafer 121, and the semiconductor wafer 301.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

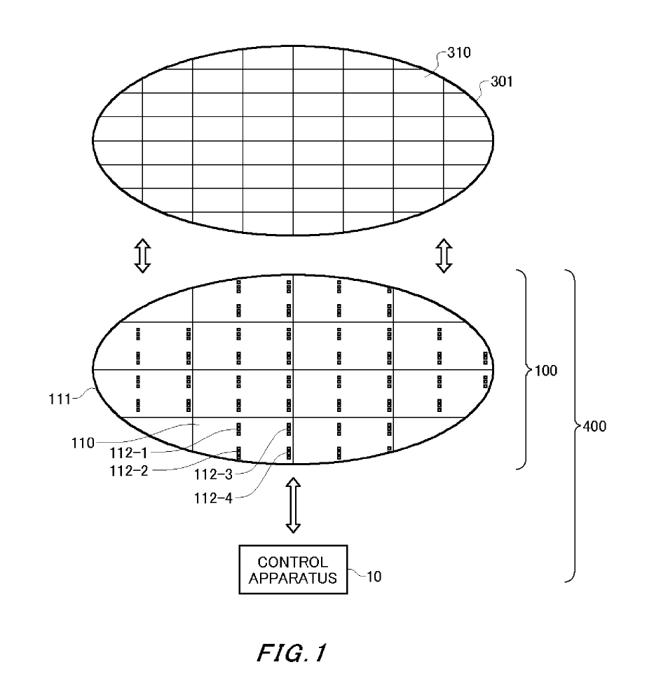

FIG. 1 shows an overview of a test system 400. The test system 400 tests a plurality of semiconductor chips 310 formed on a semiconductor wafer 301 as devices under test. The test system 400 of the present embodiment includes a test wafer unit 100 and a control apparatus 10. FIG. 1 shows an exemplary perspective view of the semiconductor wafer 301 and the test wafer unit 100.

The semiconductor wafer 301 may be disc-shaped. More specifically, the semiconductor wafer 301 may be silicon, a compound semiconductor, or some other type of semiconductor wafer. The semiconductor chips 310 may be formed on the semiconductor wafer 301 using a semiconductor process such as lithography. The semiconductor chips 310 each include an operation circuit and an internal memory.

The test wafer unit 100 includes a test wafer 111. The test wafer 111 is electrically connected to the semiconductor wafer 301. More specifically, the test wafer 111 is electrically connected en bloc to the semiconductor chips 310 formed on the semiconductor wafer 301.

The test wafer 111 may be a semiconductor wafer formed of the same semiconductor material as the semiconductor wafer 301. For example, the test wafer 111 may be a silicon wafer. The test wafer 111 may be formed of a semiconductor material having substantially the same thermal expansion coefficient as the semiconductor wafer 301. The test wafer 111 may have a shape corresponding to the semiconductor wafer 301. Here, a “corresponding shape” refers to the same shape or to a shape by which one wafer is a portion of the other.

For example, the test wafer 111 may be a wafer having the same shape as the semiconductor wafer 301. More specifically, the test wafer 111 may be disc-shaped and have a diameter substantially equal to that of the semiconductor wafer 301. The test wafer 111 may have a shape that covers a portion of the semiconductor wafer 301 when the test wafer 111 and the semiconductor wafer 301 are stacked. When the semiconductor wafer 301 is disc-shaped, the test wafer 111 may have a shape that occupies a portion of this disc, such as a half-circle shape.

A plurality of circuit blocks 110 are formed on the test wafer 111. The circuit blocks 110 are provided to correspond to the semiconductor chips 310. In the present configuration, each circuit block 110 corresponds to two or more semiconductor chips 310. In the following description, the two or more semiconductor chips 310 that are provided to correspond to each circuit block 110 may be simply referred to as the “corresponding semiconductor chips 310.”

Each circuit block 110 may be provided at a position that overlaps with a region in which the two or more corresponding semiconductor chips 310 are formed when the test wafer 111 and the semiconductor wafer 301 are stacked. By stacking the test wafer 111 and the semiconductor wafer 301, each circuit block 110 may be electrically connected to the corresponding semiconductor chips 310 to test these semiconductor chips 310.

The circuit blocks 110 may be provided on the back of the surface of the test wafer 111 facing the semiconductor wafer 301. In this case, each circuit block 110 may be electrically connected to the corresponding semiconductor chips 310 using a through-hole, also known as a via hole, formed in the test wafer 111.

A plurality of connection pads 112 may be formed on a wafer connecting surface of the test wafer 111. At least one connection pad 112 is provided for each semiconductor chip 310. For example, one connection pad 112 may be provided for each test pad in a semiconductor chip 310. In other words, when each semiconductor chip 310 includes a plurality of test pads, a plurality of connection pads 112 may be provided for each semiconductor chip 310.

For example, a number of connection pads 112 equal to the number of test pads may be formed on the test wafer 111. Each connection pad 112 is electrically connected to a test pad in a corresponding semiconductor chip 310.

The test pads are examples of test terminals. The connection pads 112 function as connection terminals that are electrically connected to the test pads. In this way, the connection pads 112 are formed on the test wafer 111 corresponding one-to-one with the test pads of the semiconductor chips 310, and are electrically connected to the corresponding test pads.

Here, an “electrical connection” may refer to a state in which the transmission of electrical signals is possible between two components. For example, the circuit blocks 110 and the test pads of the semiconductor chips 310 may be electrically connected through direct contact or through indirect contact via another conductor. For example, the test system 400 may include a probe member such as a membrane sheet between the semiconductor wafer 301 and the test wafer 111, having substantially the same diameter as these wafers. The membrane sheet includes bumps that electrically connect corresponding test pads of the circuit blocks 110 and the semiconductor chips 310 to each other. The test system 400 may include an anisotropic conductive sheet between the membrane sheet and the test wafer 111.

The circuit blocks 110 and the test pads of the semiconductor chips 310 may be electrically connected in a non-contact state, via capacitive coupling, also known as electrostatic coupling, or inductive coupling, also known as magnetic coupling, for example. A portion of the transmission lines between the circuit blocks 110 and the test pads of the semiconductor chips 310 may be optical transmission lines.

The circuit blocks 110 exchange signals with the corresponding semiconductor chips 310 via the connection pads 112. The circuit blocks 110 supply the corresponding semiconductor chips 310 with test signals, as an example of measurement signals. The circuit blocks 110 receive response signals output by the corresponding semiconductor chips 310 in response to the test signals. If the test signals are supplied to the circuit blocks 110 from the control apparatus 10 that controls the test wafer 111, the circuit blocks 110 are electrically connected to the control apparatus 10 via device-side connection terminals formed on the device connecting surface, which is the back surface of the wafer connecting surface.

If semiconductor chips 310 having the same circuit configuration are formed on the semiconductor wafer 301, the circuit blocks 110 of the test wafer 111 may have the same circuit configuration. If the test pads of each semiconductor chip 310 have the same arrangement, the circuit blocks 110 may each have the same connection pad 112 arrangement.

Each circuit block 110 may judge pass/fail of each corresponding semiconductor chip 310 by comparing a logic pattern of the corresponding response signal to a predetermined expected value pattern. Each circuit block 110 writes the pass/fail of each corresponding semiconductor chip 310 to an internal memory in the semiconductor chip 310. Each circuit block 110 may read the pass/fail from the internal memory in each corresponding semiconductor chip 310 and supply the semiconductor chip 310 with a test signal corresponding to the read pass/fail.

With the test wafer unit 100 of the present embodiment, the test results are written to the internal memories in the semiconductor chips 310, and therefore the capacity of the fail memories to be formed for the circuit blocks 110 can be drastically decreased. Depending on circumstances, fail memories might not be needed at all.

The circuit blocks 110 may output, to the control apparatus 10, the test results in the internal memories of the corresponding semiconductor chips 310. For example, when the test results in the internal memories of the corresponding semiconductor chips 310 indicate a fail, the circuit blocks 110 may transmit the test results in these internal memories to the control apparatus 10. Furthermore, the circuit blocks 110 may transmit to the control apparatus 10 test results obtained by testing necessary functions for operating the internal memories in the corresponding semiconductor chips 310. The circuit blocks 110 may write the test results of semiconductor chips 310 whose internal memories contain fail test results to internal memories in other semiconductor chips 310 that contain pass test results.

Since the test wafer 111 of the present embodiment is made of the same semiconductor material as the semiconductor wafer 301, even if the surrounding temperature fluctuates, a good electrical connection can be maintained between the test wafer 111 and the semiconductor wafer 301. Therefore, when the semiconductor wafer 301 is heated for testing, the semiconductor wafer 301 can still be accurately tested.

Since the test wafer 111 is formed of a semiconductor material, the circuit blocks 110 can be easily formed with high density on the test wafer 111. For example, the circuit blocks 110 can be easily formed with high density on the test wafer 111 with a semiconductor process using lithography or the like. Therefore, a large number of circuit blocks 110 corresponding to a large number of semiconductor chips 310 can be formed relatively easily on the test wafer 111.

When the circuit blocks 110 are provided on the test wafer 111, the size of the control apparatus 10 can be decreased. In other words, since the test system 400 of the present embodiment includes the circuits for testing the semiconductor chips 310 in the test wafer unit 100, the control apparatus 10 can test the semiconductor chips 310 by controlling the test wafer unit 100. For example, the control apparatus 10 should include a function for providing the circuit blocks 110 with notification concerning the timing at which testing is initiated or the like, a function for reading test results of the circuit blocks 110, and a function for supplying drive power for the circuit blocks 110 and semiconductor chips 310.

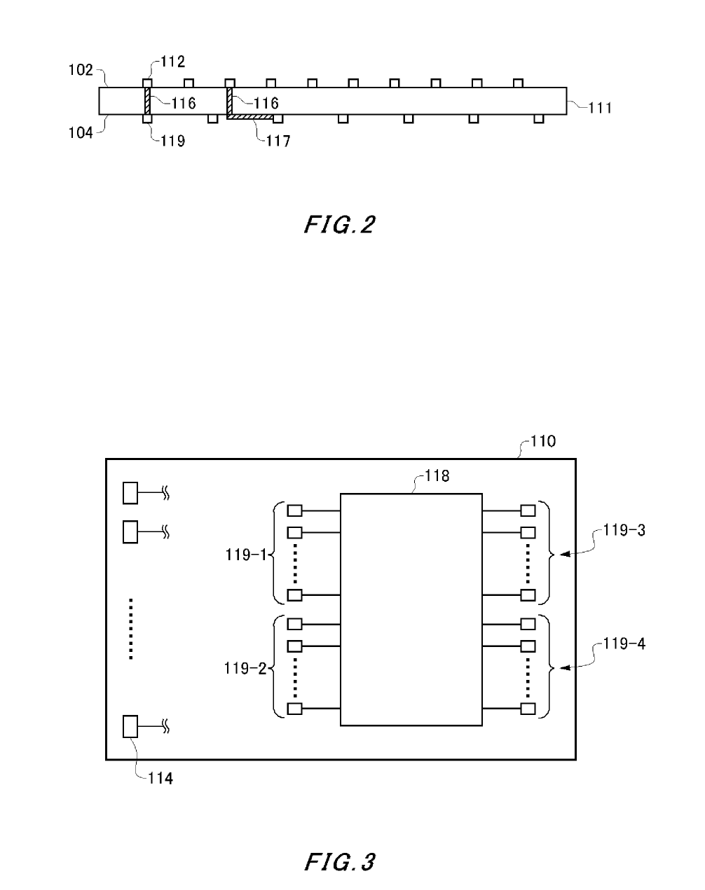

FIG. 2 is an exemplary side view of the test wafer 111. As described above, the test wafer 111 has a wafer connecting surface 102 that faces the semiconductor wafer 301 and a device connecting surface 104 on the back of the wafer connecting surface 102. The connection pads 112 are formed on the wafer connecting surface 102. A plurality of pads 119 are formed on the device connecting surface 104. The terminals of the test wafer 111 may be formed on the test wafer 111 by depositing or coating with a conductive material.

The test wafer 111 may include through-holes 116 that each provide an electrical connection between a pad 119 and a corresponding connection pad 112. Each through-hole 116 is formed to pass through the test wafer 111.

The intervals between the pads 119 may be different from the intervals between the connection pads 112. The connection pads 112 are arranged at the same intervals as the input terminals of the semiconductor chips 310, in order to be electrically connected to the input terminals. Therefore, as shown in FIG. 1, the connection pads 112 can be formed at short intervals for each semiconductor chip 310.

The pads 119, on the other hand, may be arranged at intervals wider than the intervals between the connection pads 112 corresponding to a single semiconductor chip 310. For example, the pads 119 may be arranged at uniform intervals on the device connecting surface 104 such that the distribution of the pads 119 is substantially uniform. Wiring 117 may be formed on the test wafer 111 to electrically connect the pads 119 and the through-holes 116.

Although a circuit block 110 is not shown in FIG. 2, the circuit blocks 110 may be formed on the device connecting surface 104 or the wafer connecting surface 102 of the test wafer 111. The circuit blocks 110 may instead be formed in an intermediate layer of the test wafer 111.

FIG. 3 shows an exemplary configuration of a circuit block 110. The present embodiment described an example in which the circuit block 110 is formed on the device connecting surface 104.

The circuit block 110 includes a test circuit unit 118. The circuit block 110 also includes a plurality of pads 119 and a plurality of device-side connection terminals 114. The pads 119 are electrically connected to the connection pads 112 formed on the wafer connecting surface 102, via the through-holes 116.

The test circuit unit 118 is electrically connected to the control apparatus 10 via the device-side connection terminal 114. The test circuit unit 118 may receive a control signal, a power supply signal, or the like from the control apparatus 10 via the device-side connection terminals 114.

The test circuit unit 118 tests the corresponding semiconductor chips 310 by supplying a test signal to the connection pads 112 via the pads 119. One pad 119 is provided for each connection pad 112, and one connection pad 112 is provided for each test pad of the corresponding semiconductor chips 310. For example, the pads 119-1, 119-2, 119-3, and 119-4 are respectively connected to the connection pads 112-1, 112-2, 112-3, and 112-4. Here, the connection pads 112-1, 112-2, 112-3, and 112-4 are each connected to a test pad of a different semiconductor chip 310.

The test circuit unit 118 may supply a test signal to the connection pads 112 connected to all of the corresponding semiconductor chips 310 in order to test all of the semiconductor chips 310 substantially simultaneously. The test circuit unit 118 may supply a test signal to the connection pads 112 connected to a portion of the corresponding semiconductor chips 310 in order to test this portion of the semiconductor chips 310 substantially simultaneously.

After testing this portion of the semiconductor chips 310, the test circuit unit 118 may supply a test signal to another portion of the semiconductor chips 310, excluding the above portion, in order to test this portion of the remaining semiconductor chips 310. A “portion” of the semiconductor chips 310 may refer to a single semiconductor chip 310 or to two or more semiconductor chips 310.

As described above, since the circuit blocks 110 are formed on the semiconductor test wafer 111, the test circuit units 118 having semiconductor elements can be formed with high density. Furthermore, since the circuit blocks 110 each test corresponding semiconductor chips 310, sufficient space for mounting the test circuit units 118 can be ensured. Therefore, large circuits can be mounted using the test circuit units 118, thereby decreasing the size of the control apparatus 10.

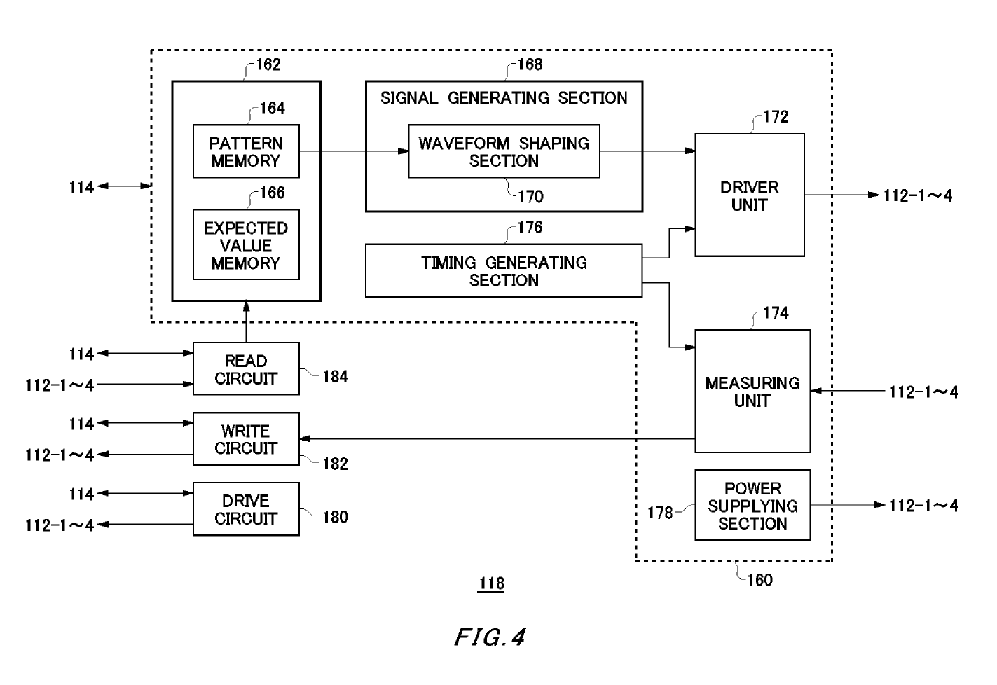

FIG. 4 is a block diagram showing an exemplary functional configuration of the test circuit unit 118. The circuit block 110 includes a test circuit 160, a driver circuit 180, a write circuit 182, and a read circuit 184. The test circuit 160 includes a pattern generating section 162, a signal generating section 168, a driver unit 172, a measuring unit 174, a timing generating section 176, and a power supplying section 178. The signal generating section 168 includes a waveform shaping section 170.

The pattern generating section 162 generates a logic pattern of a test signal. The pattern generating section 162 of the present embodiment includes a pattern memory 164 and an expected value memory 166. The pattern generating section 162 may output a logic pattern stored in advance in the pattern memory 164. The pattern memory 164 may store a logic pattern supplied from the control apparatus 10 prior to testing. The pattern generating section 162 may generate the logic pattern based on an algorithm supplied thereto in advance.

The waveform shaping section 170 shapes the waveform of the test signal based on the logic pattern provided from the pattern generating section 162. For example, the waveform shaping section 170 may shape the waveform of the test signal by outputting, for each bit period, a voltage corresponding to each logic value of the logic pattern.

The driver unit 172 outputs a test signal corresponding to the waveform supplied from the waveform shaping section 170. For example, the driver unit 172 may supply the test signal to the semiconductor chips 310 via the connection pads 112 and pads 119, according to a timing signal generated by the timing generating section 176. The driver unit 172 may supply the test signal to the operation circuits 320 of the semiconductor chips 310 via the connection pads 112 and pads 119. The test signal output from the driver unit 172 may be for performing a DC test that involves judging whether the DC power consumed by a semiconductor chip 310 fulfills certain specifications, a function test that involves judging whether a semiconductor chip 310 outputs a prescribed output signal in response to an input signal, or an analog test that involves judging whether the characteristics of the signal output by a semiconductor chip 310 fulfill certain specifications, for example.

The measuring unit 174 measures the response signals output by the semiconductor chips 310. For example, the measuring units 174 may measure the response signals output by the semiconductor chips 310, via the connection pads 112 and the pads 119, according to the timing signal generated by the timing generating section 176. The measuring unit 174 judges pass/fail of each semiconductor chip 310 according to the response signal. For example, the logic comparing section 138 may judge pass/fail of a semiconductor chip 310 based on whether the logic pattern corresponding to the response signal matches the expected value pattern provided from the pattern generating section 162. Furthermore, the logic comparing section 138 may judge the acceptability of an operation circuit of the semiconductor chip 310 based on whether the logic pattern corresponding to the response signal matches the expected value pattern provided from the pattern generating section 162.

The pattern generating section 162 may supply the measuring unit 174 with the expected value pattern stored in advance in the expected value memory 166. The expected value memory 166 may store the logic pattern provided from the control apparatus 10 prior to testing. The pattern generating section 162 may generate the expected value pattern based on an algorithm provided thereto in advance.

The write circuit 182 writes pass/fail data of a semiconductor chip 310, as judged by the measuring unit 174, to the internal memory in this semiconductor chip 310. For example, the write circuit 182 may write the pass/fail data of an operation circuit of the semiconductor chip 310 to the internal memory of this semiconductor chip 310 via a connection pad 112 and a pad 119. Each internal memory of a semiconductor chip 310 formed on the semiconductor wafer 301 may have the same address space. The write circuit 182 may write the pass/fail data to the same predetermined address in each internal memory.

In this way, the test circuits 160 judge the pass/fail of the operation circuits of the semiconductor chips 310 based on the measurement results obtained by measuring the electrical characteristics of the signals output by the semiconductor chips 310. The write circuit 182 writes the pass/fail data of the operation circuits to the internal memories.

The read circuit 184 reads the pass/fail data of the semiconductor chips 310 from the internal memories therein. The read circuit 184 may read the data stored in advance in the predetermined address by the internal memories, for example. The pattern generating section 162 outputs a logic pattern corresponding to the pass/fail data read by the read circuit 184. As a result, the signal generating section 168 generates the test signal according to the pass/fail data read by the read circuit 184. In this way, the test circuit 160 can output to each semiconductor chip 310 a test signal corresponding to the pass/fail data read by the read circuit 184.

For example, when the pass/fail data read from an internal memory by the read circuit 184 indicates a fail, the test circuit 160 may output another test signal that is to be supplied to the semiconductor chip 310 having this internal memory on a condition that the pass/fail data indicates a fail. The test circuit 160 may output, as this other test signal, a test signal for performing a test whose conditions are looser than the conditions of the test that resulted in the pass/fail data indicating fail.

For example, when the pass/fail data for a high-frequency operation test of a semiconductor chip 310 indicates a fail, this other test signal may be a test signal for performing a low-frequency operation test of the semiconductor chip 310. When the pass/fail data read by the read circuit 184 from an internal memory indicates a fail, the test circuit 160 need not output another test signal to the semiconductor chip 310 having this internal memory.

The driver circuit 180 controls the electrical connections between the internal memories of the semiconductor chips 310 and each of the write circuit 182 and the read circuit 184. For example, the driver circuit 180 may select an internal memory to which the write circuit 182 is to write pass/fail data, from among the internal memories of the two or more corresponding semiconductor chips 310, and electrically connect the selected internal memory to the write circuit 182. Furthermore, the driver circuit 180 may select an internal memory from which the read circuit 184 is to read pass/fail data, from among the internal memories of the two or more corresponding semiconductor chips 310, and electrically connect the selected internal memory to the read circuit 184.

The power supplying section 178 supplies power for driving the semiconductor chips 310. For example, the power supplying section 178 may supply the semiconductor chips 310 with power corresponding to the power provided from the control apparatus 10 during testing. The power supplying section 178 may supply the power to the circuits that realize the functional configuration of the test circuit 160.

With the test circuit unit 118 having the above configuration, a test system 400 can be realized in which the control apparatus 10 has a decreased size. For example, a general personal computer or the like can be used as the control apparatus 10.

As described above, the test wafer 111 may include, a plurality of test circuits 160, a plurality of write circuits 182, and a plurality of read circuits 184 corresponding to a plurality of semiconductor chips 310. The test circuits 160 each supply the operation circuits of the corresponding semiconductor chips 310 with a test signal. Each test circuit 160 measures the electric characteristics of the signals output by the operation circuits in response to the test signal. The write circuits 182 each write, to the corresponding internal memories, data corresponding to measurement results of the corresponding test circuit 160.

The read circuits 184 each read the data stored in advance at predetermined addresses in the corresponding internal memories. The test circuits 160 supply the corresponding operation circuits with the test signals corresponding to the data read by the corresponding read circuits 184.

The test system 400 may sequentially electrically connect a plurality of test wafers 111 to the semiconductor wafer 301. For example, the test system 400 may sequentially electrically connect a plurality of test wafers 111 for performing different types of tests to the semiconductor wafer 301. The control apparatus 10 may designate, for each write circuit 182 of a first test wafer 111, a prescribed address in the internal memories to which the write circuit 182 writes the measurement result. The control apparatus 10 then designates, for each read circuit 184 of a second test wafer 111, the prescribed address in the internal memories from which the read circuit 184 reads the measurement results. At this time, the control apparatus 10 may cause the test circuits 160 to output test signals corresponding to the measurement results to the operation circuits of the semiconductor chips 310.

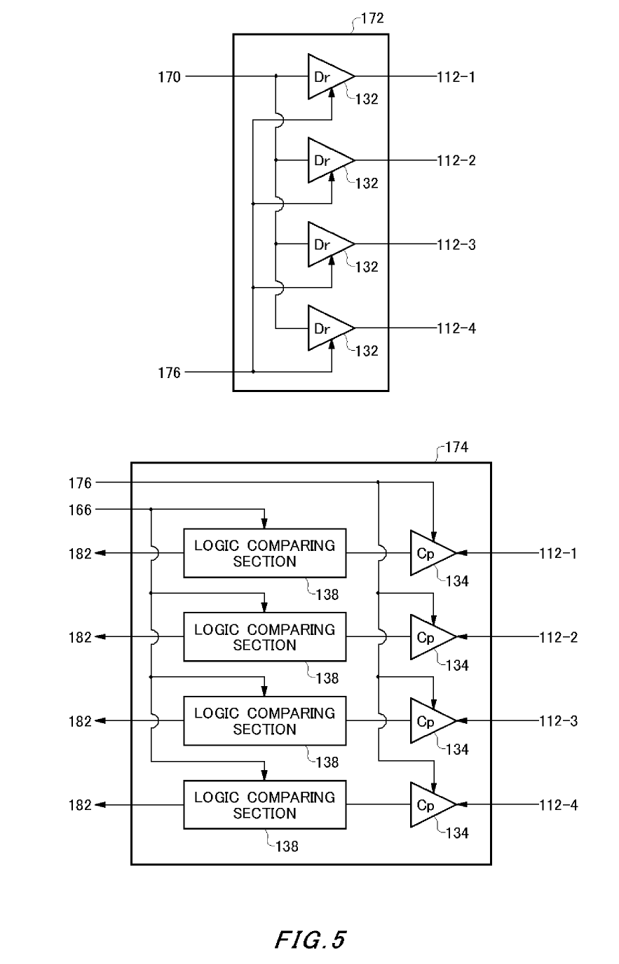

FIG. 5 is a block diagram showing exemplary functional configurations of a driver unit 172 and a measuring unit 174. The driver unit 172 includes a plurality of drivers 132. The measuring unit 174 includes a plurality of comparators 134 and a plurality of logic comparing sections 138.

The drivers 132 output a test signal to each semiconductor chip 310 corresponding to the circuit block 110. One driver 132 may be provided for each corresponding semiconductor chip 310. The drivers 132 are connected to the corresponding semiconductor chips 310 via the pads 119 and the connection pads 112. The test signal output by the drivers 132 are supplied to the semiconductor chips 310 via the pads 119 and the connection pads 112.

The drivers 132 output, to the corresponding semiconductor chips 310, the test signal corresponding to the waveform supplied from the waveform shaping section 170. Each driver 132 may output the test signal according to the timing signal supplied from the timing generating section 176. For example, each driver 132 may output a test signal having the same period as the timing signal.

The comparators 134 measure the response signals output by the semiconductor chips 310 corresponding to the circuit block 110. One comparator 134 may be provided for each corresponding semiconductor chip 310. The comparators 134 may be connected to the corresponding semiconductor chips 310 via the connection pads 112 and the pads 119. The signals from the corresponding semiconductor chips 310 are supplied to the comparators 134 via the connection pads 112 and the pads 119. The comparators 134 may measure the logic patterns of the response signals by sequentially detecting the logic values of the response signals according to strobe signals supplied from the timing generating section 176.

The logic comparing sections 138 judge pass/fail of the semiconductor chips 310 corresponding to the circuit block 110, based on the logic patterns of the response signals measured by the comparators 134. One logic comparing section 138 may be provided for each semiconductor chip 310 corresponding to the circuit block 110. The logic comparing sections 138 judge pass/fail of the semiconductor chips 310 based on the logic patterns of the response signals from the semiconductor chips 310 measured by the comparators 134. For example, each logic comparing section 138 may judge pass/fail of the corresponding semiconductor chip 310 based on whether the logic pattern detected by the corresponding comparator 134 matches the expected value pattern provided from the pattern generating section 162. The comparison results of the logic comparing sections 138 are supplied to the write circuit 182 and written to the internal memories in the corresponding semiconductor chips 310.

As described above, the driver unit 172 can receive the test signal generated by the signal generating section 168 in parallel and supply signals corresponding to the test signal to the semiconductor chips 310 substantially simultaneously with the test signal. In this way, each test circuit 160 can generate a test signal that is shared by the two or more semiconductor chips 310 to be tested, and the test signal can be supplied substantially simultaneously to the two or more semiconductor chips 310 via the connection pads 112. The measuring unit 174 can receive the response signals from the semiconductor chips 310 at substantially the same time to judge pass/fail of the semiconductor chips 310. Accordingly, each test circuit 160 can test the plurality of corresponding semiconductor chips 310 substantially simultaneously.

One comparator 134 and the logic comparing section 138 that judges pass/fail of a semiconductor chip 310 based on the response signal measured by this comparator 134 function as a measuring section that measures the output signal of the semiconductor chip 310. Accordingly, the driver unit 172 includes a plurality of measuring sections that are provided respectively for the two or more semiconductor chips 310 to be tested and that each measure the signal output by the corresponding semiconductor chip 310.

As described in relation to FIG. 4, the test circuit unit 118 may include one signal generating section 168. In other words, the signal generating section 168 is provided in common for the two or more semiconductor chips 310 to be tested. On the other hand, one driver 132 is provided for each of the two or more semiconductor chips 310 to be tested. The drivers 132 provided for the two or more semiconductor chips 310 receive the test signal generated by the signal generating section 168 in parallel and each supply a signal corresponding to the test signal to a test pad of a semiconductor chip 310 via a connection pad 112.

Since the drivers 132 are provided corresponding to the two or more semiconductor chips 310 to be tested, the circuit blocks 110 of the test wafer 111 may be provided with low-output drivers 132. Therefore, the drivers 132 to be implemented in the circuit blocks 110 of the test wafer 111 can be made smaller and a plurality of drivers 132 can be easily implemented in the circuit blocks 110.

In the configuration of the present embodiment, one driver 132 is provided for each semiconductor chip 310, but a plurality of drivers 132 may be provided for each semiconductor chip 310. For example, drivers 132 corresponding to the test pads of each semiconductor chip 310 may be provided.

As described in relation to FIGS. 4 and 5, when performing substantially simultaneous testing of two or more semiconductor chips 310 to be tested, the pattern generating section 162, the signal generating section 168, the timing generating section 176, and the power supplying section 178 can be provided in common to the two or more semiconductor chips 310 to be tested. The write circuit 182, the read circuit 184, and the driver circuit 180 can also be provided in common to the two or more semiconductor chips 310 to be tested. Therefore, the area in which the test circuit 160, the write circuit 182, the read circuit 184, and the driver circuit 180 are implemented can be decreased compared to a case in which circuits for realizing the functions of the pattern generating section 162, the signal generating section 168, the timing generating section 176, and the power supplying section 178 are provided for every one of the semiconductor chips 310.

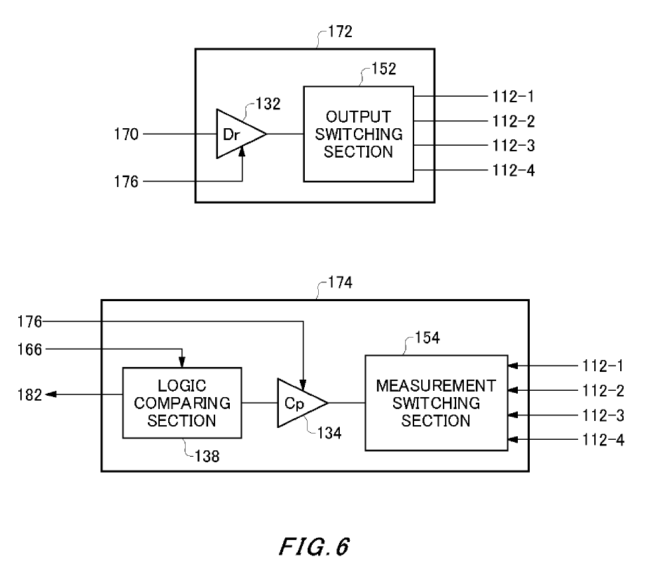

FIG. 6 is a block diagram showing another functional configuration of a driver unit 172 and a measuring unit 174. The driver unit 172 includes a driver 132 and an output switching section 152. The measuring unit 174 includes a logic comparing section 138, a comparator 134, and a measurement switching section 154.

The operation of the driver 132 may be the same as the operation of the driver 132 described in relation to FIG. 5, except that this driver 132 outputs the test signal to the output switching section 152. The output switching section 152 is connected to the semiconductor chips 310 corresponding to the circuit block 110 via the pads 119 and connection pads 112. The output switching section 152 selects the semiconductor chip 310 to which the test signal from the driver 132 is output.

More specifically, the output switching section 152 selects which connection pad 112 electrically connected to a semiconductor chip 310 the test signal from the driver is supplied to. In this way, the output switching section 152 switches which connection pad 112 electrically connected to a test pad of a semiconductor chip 310 the signal output by the driver 132 is supplied to.

The measurement switching section 154 is connected to the semiconductor chips 310 corresponding to the circuit block 110 via the connection pads 112 and pads 119. The measurement switching section 154 selects the semiconductor chip 310 from which to acquire the response signal. More specifically, the measurement switching section 154 selects which connection pad 112 electrically connected to a semiconductor chip 310 is connected to the comparator 134. In this way, the measurement switching section 154 can switch which semiconductor chip's 310 output response signal is supplied to the comparator 134.

The output switching section 152 may sequentially switch which connection pad 112 electrically connected to a test pad of a semiconductor chip 310 the signal output by the driver is supplied to. The measurement switching section 154 may sequentially switch which semiconductor chip's 310 output response signal is supplied to the comparator 134.

The operation of the comparator 134 may be the same as the operation of the comparator 134 described in relation to FIG. 5, except that this comparator 134 acquires the response signal from the measurement switching section 154. The operation of the logic comparing section 138 may be the same as the operation of the comparator 134 described in FIG. 5. One comparator 134 and the logic comparing section 138 that judges pass/fail of a semiconductor chip 310 based on the response signal measured by this comparator 134 function as a measuring section that measures the output signal of the semiconductor chip 310. Accordingly, the measuring unit 174 includes a measuring section that is provided in common for the two or more semiconductor chips 310 to be tested and that sequentially measures the signals output by the two or more semiconductor chips 310.

In the functional configuration of this block diagram, the circuit block 110 includes one driver 132, one output switching section 152, one logic comparing section 138, one comparator 134, and one measurement switching section 154 for the two or more semiconductor chips 310 corresponding to the circuit block 110. In other configurations, the circuit block 110 may include a number of drivers 132, output switching sections 152, logic comparing sections 138, comparators 134, and measurement switching sections 154 whereby the number of each component is less than the number of semiconductor chips 310 corresponding to the circuit block 110.

In this way, the switching control by the output switching section 152 and the measurement switching section 154 enables the test circuit 160 to generate a common test signal for the two or more semiconductor chips 310 to be tested and sequentially supply the test signal to the two or more semiconductor chips 310 via the connection pads 112. Furthermore, with this configuration, in addition to the functional configuration described in relation to FIGS. 4 and 5, the driver 132, the comparator 134, and the logic comparing section 138 can also be provided in common for two or more semiconductor chips 310 to be tested. As a result, the area necessary for implementing the test circuit 160, the write circuit 182, the read circuit 184, and the driver circuit 180 can be further decreased.

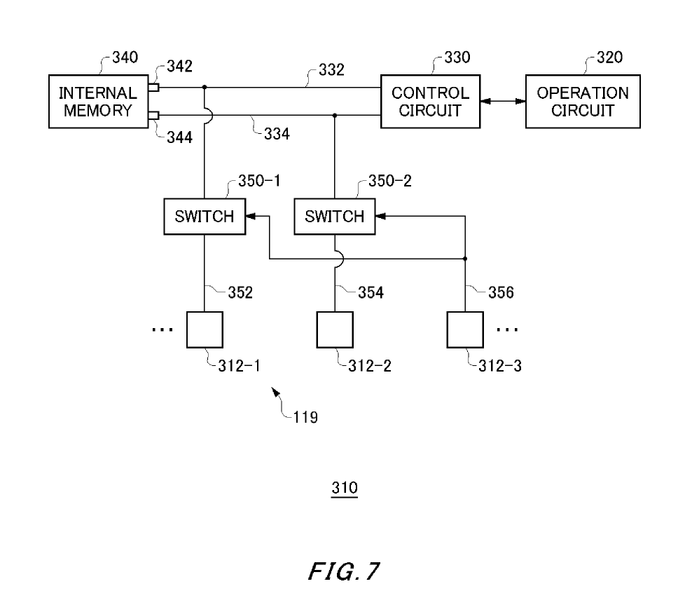

FIG. 7 is a block diagram showing an exemplary functional configuration of a semiconductor chip 310. The semiconductor chip 310 includes an operation circuit 320, a control circuit 330, an internal memory 340, a data terminal 342, an address terminal 344, an internal data terminal line 332, an internal address terminal line 334, switches 350, an external data terminal line 352, an external address terminal line 354, an external switch line 356, and a plurality of test pads 312. The function of the semiconductor chip 310 is realized by the operation of the operation circuit 320. The internal memory 340 is used for the operation of the operation circuit 320.

When the semiconductor chip 310 is operating, the operation circuit 320 may write operation data of the operation circuit 320 to the internal memory 340. When the semiconductor chip 310 is operating, the operation circuit 320 may read from the internal memory 340 the data written to the internal memory 340, and use the read data. When the semiconductor chip 310 is operating, the operation circuit 320 may delete from the internal memory 340 the data written to the internal memory 340. When the semiconductor chip 310 is operating, the operation circuit 320 can write data to the internal memory 340 via the control circuit 330.

The control circuit 330 controls the writing of data to the internal memory 340. The control circuit 330 is electrically connected to the data terminal 342 of the internal memory 340 by the internal data terminal line 332. The control circuit 330 is electrically connected to the address terminal 344 of the internal memory 340 by the internal address terminal line 334.

When writing data to the internal memory 340, the control circuit 330 outputs to the address terminal 344, via the internal address terminal line 334, an electric signal designating a memory address to be written to. When writing data to the internal memory 340, the control circuit 330 outputs to the data terminal 342, via the internal data terminal line 332, an electrical signal designating the data to be written. The internal memory 340 stores the data indicating the electrical signals to be input to the data terminal 342 in a memory address indicating the electric signal to be input to the address terminal 344.

When reading data from the internal memory 340, the control circuit 330 outputs to the address terminal 344, via the internal address terminal line 334, an electric signal designating a memory address to read from. The internal memory 340 outputs to the data terminal 342 an electric signal indicating data stored in the memory address indicated by the electric signal input to the address terminal 344. The control circuit 330 reads the data from the internal memory 340 by acquiring, via the internal data terminal line 332, the electric signal output to the data terminal 342.

The external data terminal line 352 electrically connects the data terminal 342 to the test pad 312-1. The external address terminal line 354 electrically connects the address terminal 344 to the test pad 312-2. The switch 350-1 is provided on the external data terminal line 352 and controls the electrical connection between the test pads 312 and the data terminal 342. The switch 350-2 is provided on the external address terminal line 354 and controls the electrical connection between the test pads 312 and the address terminal 344. The test pad 312-1 and the test pad 312-2 function as external memory access terminals connected to external circuits. The test pad 312-1 and the test pad 312-2 may be larger that the data terminal 342 and the address terminal 344.

In this way, each semiconductor chip 310 includes lines, such as the external data terminal line 352 and the external address terminal line 354, for electrically connecting the data terminal 342 and the address terminal 344 of the internal memory 340 to the test pad 312-1 and the test pad 312-2 provided for the semiconductor chip 310. Furthermore, each semiconductor chip 310 includes switches 350 that control the electrical connections between (i) the test pads 312 and (ii) the data terminal 342 and the address terminal 344 of the internal memory 340.

The external switch line 356 electrically connects the test pad 312-3 to the switches 350. The switches 350 operate according to electric signals input from the test pad 312-3 via the external switch line 356. More specifically, the switch 350-1 electrically connects the test pad 312-1, which is connected to the external data terminal line 352, to the data terminal 342 by closing when a prescribed electrical signal is received from the test pad 312-3 via the external switch line 356. Similarly, the switch 350-2 electrically connects the test pad 312-2, which is connected to the external address terminal line 354, to the address terminal 344 by closing when a prescribed electrical signal is received from the test pad 312-3 via the external switch line 356.

The switch 350-1 and the switch 350-2 may close when voltage greater than or equal to a predetermined value is input thereto. The switch 350-1 and the switch 350-2 may be in an open state when no electric signal is provided from the outside to the test pad 312-3 connected to the external switch line 356.

The driver circuit 180 outputs electric signals to the test pad 312-3 via the pad 119 and the connection pad 112 connected to the test pad 312-3. For example, when the write circuit 182 and the read circuit 184 write and read data to and from internal memory 340 via the test pad 312-1 and the test pad 312-2, the driver circuit 180 outputs a prescribed electric signal to the test pad 312-3 to cause the switch 350 of the corresponding semiconductor chip 310 to electrically connect the test pads 312-1 and 312-2 to the data terminal 342 and the address terminal 344. For example, when the write circuit 182 and the read circuit 184 write and read data to and from internal memory 340 via the test pad 312-1 and the test pad 312-2, the driver circuit 180 may output a voltage that is greater than or equal to a prescribed value to the test pad 312-3.

The write circuit 182 and the read circuit 184 may write and read data to and from the internal memory 340 via the test pad 312-1 and the test pad 312-2. More specifically, the write circuit 182 and the read circuit 184 may be controlled by the driver circuit 180 to write and read data to and from the internal memory 340, via the test pad 312-1 and the test pad 312-2, while the data terminal 342 and the address terminal 344 are electrically connected to the test pads 312 by the switches 350.

As described above, each semiconductor chip 310 includes a control circuit 330 that controls the writing and reading of data to and from the internal memory 340 therein. The write circuit 182 and the read circuit 184 may write and read data to and from the internal memory 340 via the control circuit 330. For example, the control circuit 330 may be electrically connected to the test pads 312. The write circuit 182 and the read circuit 184 may output, to the pads 119 and the connection pads 112 connected to these test pads 312, electric signals causing the control circuit 330 to write data to or read data from the internal memory 340.

The semiconductor chip 310 may control the switches 350 instead of the driver circuit 180. For example, when instructions indicating that the semiconductor chip 310 is to enter a test state are received from the outside, the semiconductor chip 310 may set the switches 350 to a closed state.

The semiconductor chip 310 may include a register for setting the state of the semiconductor chip 310. The states of the semiconductor chip 310 include a test state in which the semiconductor chip 310 is tested by the test system 400. When an electric signal setting the semiconductor chip 310 to the test state is supplied to the register, the semiconductor chip 310 may set the switches 350 to the closed state. As a result, the test pad 312-1 is electrically connected to the data terminal 342 and the test pad 312-2 is electrically connected to the address terminal 344.

When the register is not provided with an electric signal for setting the semiconductor chip 310 to the test state, the semiconductor chip 310 may set the switches 350 in the open state. As a result, the test pad 312-1 is electrically disconnected from the data terminal 342 and the test pad 312-2 is electrically disconnected from the address terminal 344.

When testing the semiconductor chip 310, the driver circuit 180 may output the electric signal for setting the test state to the register of the semiconductor chip 310 in order to set this semiconductor chip 310 to the test state. The driver circuit 180 may acquire from the control apparatus 10 register information to be output when setting the semiconductor chip 310 to the test state.

The internal memory 340 may be a semiconductor memory formed by semiconductor elements. The internal memory 340 may be a non-volatile memory. For example, the internal memory 340 may be a non-volatile random access memory.

The write circuit 182 and the read circuit 184 may acquire from the control apparatus 10 control information for writing data to or reading data from the internal memory 340. The write circuit 182 and the read circuit 184 may write or read the data to or from the internal memory 340 based on the control information received from the control apparatus 10. This control information may include an output format for a memory address output to the address terminal 344, specifications for the write data output to the address terminal 344, specifications for the read data output from the address terminal 344, or the like. When writing or reading data to or from the internal memory 340 via the control circuit 330, control specifications for the control circuit 330 may also be included in the control information.

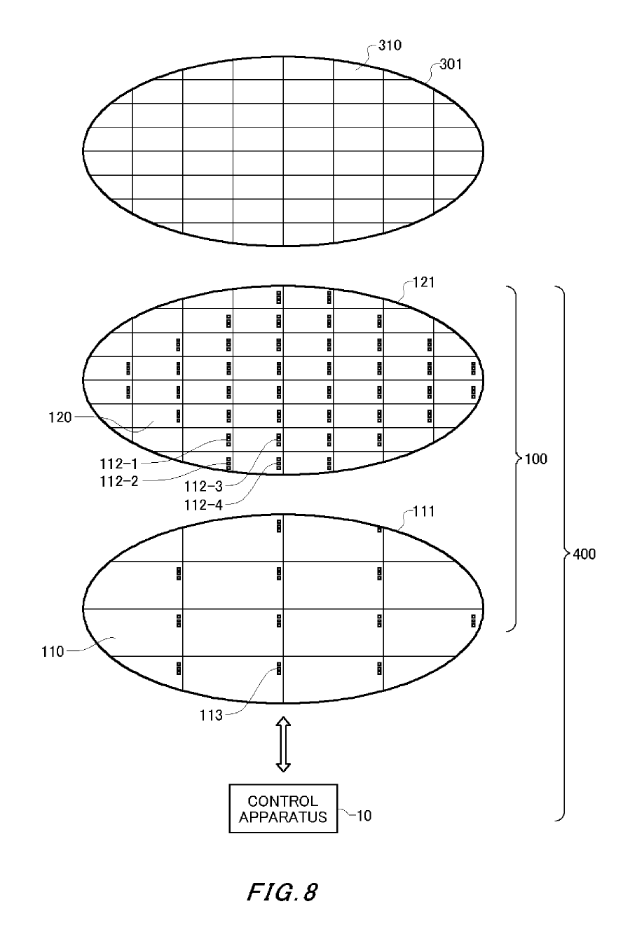

FIG. 8 shows another exemplary configuration of the test wafer unit 100. The test wafer unit 100 of the present embodiment includes a test wafer 111 and a connection wafer 121. The test wafer 111 of the present embodiment is the same as the test wafer 111 described in relation to FIGS. 1 to 7, except that instead of the connection pads 112 described in FIGS. 1 to 7, this test wafer 111 includes a number of intermediate pads 113 that is less than the number of connection pads 112. The following omits descriptions of the configurational elements of the test wafer 111 except for those that differ from the configurational elements of the test wafer 111 described in relation to FIGS. 1 to 7.

The connection wafer 121 is provided between the test wafer 111 and the semiconductor wafer 301, and electrically connects the test wafer 111 to the semiconductor wafer 301. The connection wafer 121 includes a plurality of circuit blocks 120 corresponding to the plurality of semiconductor chips 310. The circuit blocks 120 of the connection wafer 121 are provided to correspond one-to-one with the semiconductor chips 310 of the semiconductor wafer 301. The circuit blocks 120 are electrically connected to the corresponding semiconductor chips 310. The connection wafer 121 electrically connects the circuit blocks 110 of the test wafer 111 to the semiconductor chips 310 of the semiconductor wafer 301.

The test wafer 111 and the connection wafer 121 may be formed of the same semiconductor material as the semiconductor wafer 301, and may have shapes corresponding to the semiconductor wafer 301. As described in relation to FIG. 1, “corresponding shapes” refers to identical shapes or shapes by which one shape is a portion of the other. The test wafer 111 and the connection wafer 121 may be substantially the same shape.

In the present embodiment, each circuit block 110 is provided to correspond to two or more semiconductor chips 310 and two or more circuit blocks 120. In the following description, the two or more circuit blocks 120 corresponding to each of the circuit blocks 110 may be referred to simply as the “corresponding circuit blocks 120.”

Each circuit block 120 may be provided at a position that overlaps with the corresponding semiconductor chip 310 when the connection wafer 121 and the semiconductor wafer 301 are stacked. Each circuit block 110 may be provided at a position that overlaps with a region where the corresponding circuit block 120 is formed when the test wafer 111 and the connection wafer 121 are stacked.

By stacking the test wafer 111 and the connection wafer 121, each circuit block 110 is electrically connected to the corresponding circuit blocks 120, and electric signals are supplied to the circuit blocks 120. By stacking the test wafer 111 and the connection wafer 121 on the semiconductor wafer 301, each circuit block 120 is electrically connected to the corresponding semiconductor chip 310, and the test signal supplied from the corresponding circuit block 110 is supplied to the corresponding semiconductor chip 310.

The connection wafer 121 may be electrically connected to the test wafer 111 via an anisotropic conductive sheet. The connection wafer 121 may be electrically connected to the semiconductor wafer 301 via an anisotropic conductive sheet and a membrane having bumps. The control apparatus 10 may control the test circuit units 118 of the circuit blocks 110, in the same manner as the control apparatus 10 described in FIGS. 1 to 7.

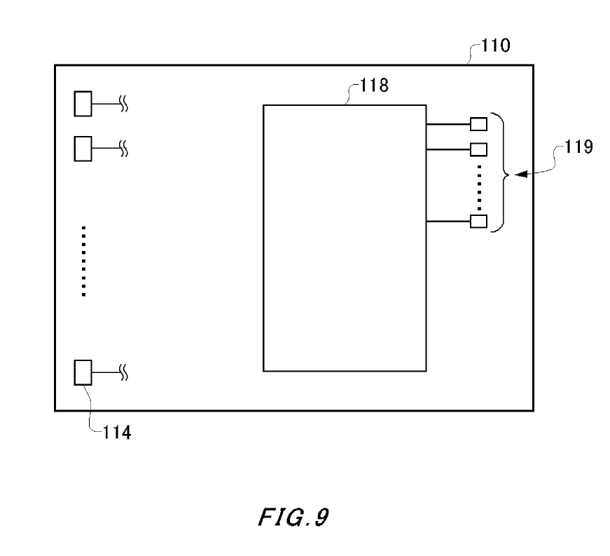

FIG. 9 shows an exemplary configuration of a circuit block 110 in the test wafer 111. The circuit block 110 differs from the circuit block 110 described in relation to FIG. 3 in that the this circuit block 110 has fewer pads 119. For example, each circuit block 110 has a number of pads 119 equal to the number of test pads 312 of a portion of the corresponding semiconductor chips 310. As an example, a circuit block 110 may have a number of pads 119 equal to the number of test pads 312 of one of the corresponding semiconductor chips 310.

Each pad 119 is electrically connected to the connection wafer 121. The pads 119 and the test circuit units 118 may be formed on a surface of the test wafer 111 facing the connection wafer 121, or may be formed on the back of this surface. If the pads 119 are formed on the back of the surface facing the connection wafer 121, each pad 119 may be electrically connected to the connection wafer 121 via a through-hole 116, as described in relation to FIG. 2. For example, each pad 119 may be electrically connected to an intermediate pad 113, which is electrically connected to the connection wafer 121, via a through-hole 116, as described in relation to FIG. 2.

The remaining configuration of the circuit block 110 may be the same as the configuration of the circuit block 110 described in relation to FIG. 3. The test circuit unit 118 may have the same functional configuration as the test circuit unit 118 described in relation to FIG. 4.

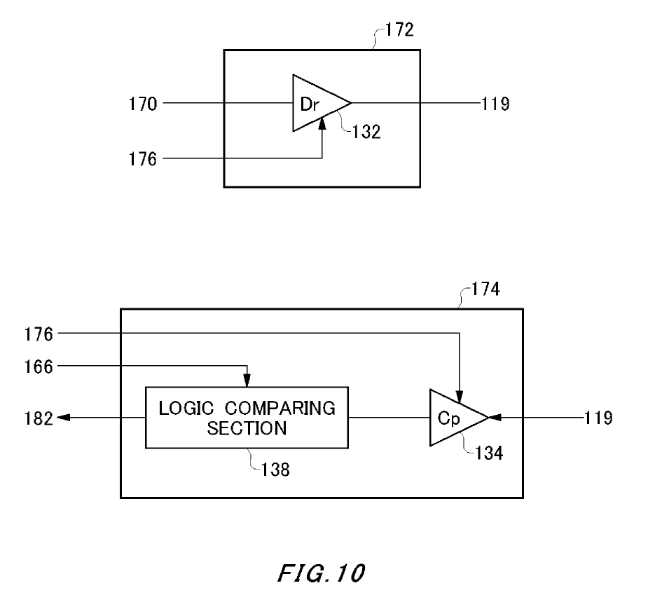

FIG. 10 shows an exemplary functional configuration of a driver unit 172 and a measuring unit 174. The driver unit 172 and the measuring unit 174 of the present embodiment differ from the driver unit 172 and the measuring unit 174 described in relation to FIG. 6 in that the output switching section 152 and the measurement switching section 154 are not included.

The driver 132 in the present embodiment is electrically connected to a pad 119, and outputs a test signal to the pad 119. The comparator 134 is electrically connected to the pad 119, and acquires the response signal from the semiconductor chip 310 via the pad 119. The function and operation of the logic comparing section 138, the function and operation of the driver 132 other than the above point, and the function and operation of the comparator 134 other than the above point are substantially the same as the function and operation of the corresponding components described in relation to FIG. 6, and therefore further explanation is omitted.

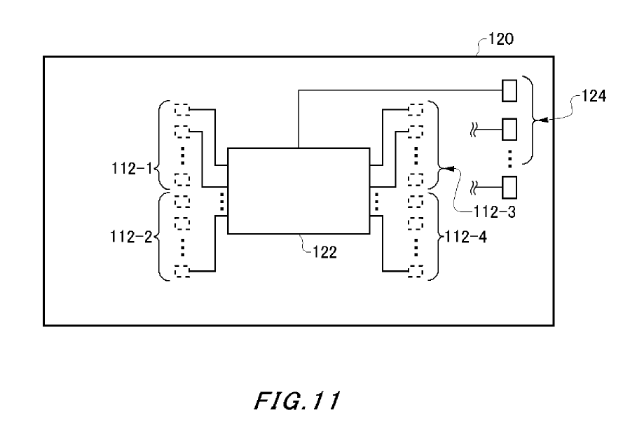

FIG. 11 shows an exemplary configuration of a circuit block 120 in the connection wafer 121. The circuit block 120 includes an input/output switching section 122, a plurality of intermediate pads 124, and a plurality of connection pads 112.

The input/output switching section 122 and the intermediate pads 124 may be provided on a surface of the connection wafer 121 facing the test wafer 111. The plurality of connection pads 112, which electrically connect to the semiconductor chip 310, are provided on the back of the surface of the connection wafer 121 that the input/output switching section 122 and the intermediate pad 124 are provided on, i.e. on the surface facing the semiconductor wafer 301. The intermediate pads 124 are electrically connected to the pads 119 of the corresponding circuit block 110 via the intermediate pads 113.

The input/output switching section 122 selects which connection pad 112 is electrically connected to each intermediate pad 124. For example, the input/output switching section 122 may include switches that switch the connections between the intermediate pads 124 and the connection pads 112. The circuit block 110 may include an input/output switching section 122 for each intermediate pad 124.

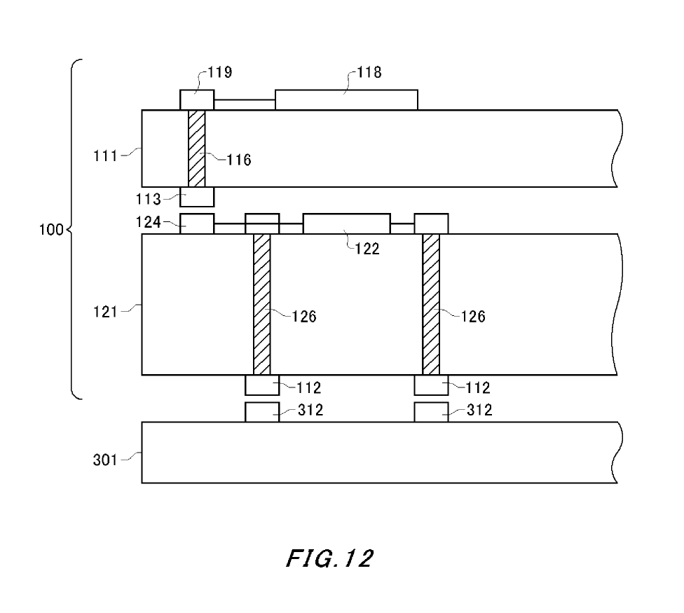

FIG. 12 shows connections between the test wafer 111, the connection wafer 121, and the semiconductor wafer 301. FIG. 12 shows a partial cross section of the test wafer 111, the connection wafer 121, and the semiconductor wafer 301.

A plurality of test circuit units 118 are formed on the top surface of the test wafer 111. Each test circuit unit 118 is electrically connected to an intermediate pad 124 of the connection wafer 121 arranged below the test wafer 111, via a pad 119, a through-hole 116, and an intermediate pad 113.

The input/output switching section 122 is formed on the top surface of the connection wafer 121, which faces the test wafer 111. The input/output switching section 122 is electrically connected to the pad 119 of the test wafer 111 via the intermediate pad 124 provided on the top surface of the connection wafer 121.

The input/output switching section 122 is electrically connected to the connection pads 112 provided on the bottom surface of the connection wafer 121, which faces the semiconductor wafer 301. The input/output switching section 122 may be electrically connected to the connection pads 112 via through-holes 126 that pass through the connection wafer 121. The input/output switching section 122 selects which connection pad 112 is connected to the intermediate pad 124.

Here, the connection pads 112 correspond one-to-one with the test pads 312 of the semiconductor chips 310, and are electrically connected to the corresponding test pads. The connection pads 112 may be provided at intervals that are the same as the intervals between the test pads 312 of the semiconductor wafer 301. The intermediate pads 124 are provided at the same intervals as the pads 119 of the test wafer 111, and therefore the intermediate pads 124 may be provided at different intervals than the connection pads 112.

In this way, the input/output switching section 122 can select a test pad 312 to be electrically connected to a pad 119. For example, the input/output switching section 122 can sequentially switch which connection pad 112 electrically connected to a test pad 312 of a semiconductor chip 310 the signal output by the driver 132 is supplied to. Furthermore, the input/output switching section 122 can sequentially switch which semiconductor chip's 310 output signal is supplied to the pad 119 connected to the comparator 134. In this way, the connection wafer 121 can supply the two or more semiconductor chips 310 to be tested by a test circuit 160 with a test signal generated by the test circuit 160.

The connection wafer 121 may be thicker than the test wafer 111. In other words, the test wafer 111 may be a relatively thin wafer. By using a thin wafer as the test wafer 111, the time needed to form the through-holes 116 in the test wafer 111 can be shortened, thereby decreasing the damage to the test circuit unit 118 during formation of the through-holes 116. By fixing the test wafer 111 to the connection wafer 121, which is relatively thick, the strength of the test wafer unit 100 can be improved.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process.

Even if the process flow is described using phrases such as “first” or “next” in the claims, embodiments, or diagrams, it does not necessarily mean that the process must be performed in this order.

As made clear from the above, the embodiments of the present invention can be used to realize a test wafer and a test system for testing a plurality of semiconductor chips formed on a semiconductor wafer and a semiconductor wafer on which a plurality of semiconductor chips are formed.

What is claimed is:

1. A test wafer that tests a plurality of semiconductor chips that are formed on a semiconductor wafer and that each include an operation circuit and an internal memory, the test wafer comprising:
a plurality of test circuits that correspond to the plurality of semiconductor chips, supply the operation circuits of the corresponding semiconductor chips with measurement signals, and measure electrical characteristics of signals output by the operation circuits in response to the measurement signals; and
a plurality of write circuits that correspond to the plurality of semiconductor chips and each write, to the internal memory of the corresponding semiconductor chip, data corresponding to a measurement result of the corresponding test circuit.

2. The test wafer according to claim 1, wherein
the test circuits judge pass/fail of the operation circuits based on the measurement results, and
each write circuit writes pass/fail data of the operation circuit to the internal memory.

3. The test wafer according to claim 2, wherein
each internal memory has the same address space, and
each write circuit writes the pass/fail data to the same predetermined address in each internal memory.

4. The test wafer according to claim 3, further comprising a plurality of read circuits that correspond to the semiconductor chips and each read data stored in advance in the corresponding internal memory at a predetermined address, wherein
each test circuit supplies the corresponding operation circuit with the measurement signal according to the data read by the corresponding read circuit.

5. The test wafer according to claim 4, wherein
each semiconductor chip includes a control circuit that controls writing and reading of data to and from the internal memory, and
the write circuits and the read circuits write and read the data to and from the internal memories via the control circuits.

6. The test wafer according to claim 4, wherein
each semiconductor chip includes wiring that electrically connects a data terminal and an address terminal of the internal memory to a test terminal provided in the semiconductor chip, and
the write circuits and the read circuits write and read data to and from the internal memories via the test terminals.

7. The test wafer according to claim 6, wherein
each semiconductor chip includes a switch that controls electrical connections between (i) the data terminal and the address terminal of the internal memory and (ii) the test terminal, and
the test wafer comprises a plurality of driver circuits that correspond to the semiconductor chip and that each, when the corresponding write circuit and read circuit write or read data to or from the internal memory via the test terminal, cause the switch of the corresponding semiconductor chip to electrically connect the test terminal to the data terminal and the address terminal.

8. A test system that tests a plurality of semiconductor chips that are formed on a semiconductor wafer and that each include an operation circuit and an internal memory, the test system comprising:
a test wafer that is electrically connected to the semiconductor wafer; and
a control apparatus that controls the test wafer, wherein the test wafer includes:
a plurality of test circuits that correspond to the plurality of semiconductor chips, supply the operation circuits of the corresponding semiconductor chips with measurement signals, and measure electrical characteristics of signals output by the operation circuits in response to the measurement signals; and
a plurality of write circuits that correspond to the plurality of semiconductor chips and each write, to the internal memory of the corresponding semiconductor chip, data corresponding to a measurement result of the corresponding test circuit.

9. The test system according to claim 8, further comprising a plurality of read circuits that correspond to the semiconductor chips and each read data stored in advance in the corresponding internal memory at a predetermined address, wherein
each test circuit supplies the corresponding operation circuit with the measurement signal according to the data read by the corresponding read circuit.

10. The test system according to claim 9, wherein
the test system electrically connects a plurality of test wafers sequentially to the semiconductor wafer,
the control apparatus designates a predetermined address in the internal memories for the write circuits of a first test wafer among the test wafers and causes the write circuits of the first test wafer to write the measurement results to the predetermined address in the internal memories, and
the control apparatus designates the predetermined address for the read circuits of a second test wafer among the test wafers and causes the read circuits of the second test wafer to read the measurement results from the predetermined address of the internal memory.

11. A semiconductor wafer on which are formed a plurality of semiconductor chips, wherein each semiconductor chip includes:
an internal memory;
an external memory access terminal connected to an external circuit; and
a switch that controls electrical connection between (i) a data terminal and an address terminal of the internal memory and (ii) the external memory access terminal.
